(19) United States
(12) Patent Application Publication
(10) Pub. No.: US 2015/0253374 A1
(43) Pub. Date: Sep. 10, 2015

(54) CHIP TO PACKAGE INTERACTION TEST VEHICLE AND METHOD FOR TESTING CHIP TO PACKAGE INTERACTION USING THE SAME

(71) Applicant: SAMSUNG ELECTRONICS CO., LTD., SUWON-SI (KR)

(72) Inventors: SANG-MAN LEE, SEOUL (KR); YOUNG-MIN KANG, YONGIN-SI (KR); YONG-SEUNG BANG, SEOUL (KR)

(21) Appl. No.: 14/620,327

(22) Filed: Feb. 12, 2015

(30) Foreign Application Priority Data
Mar. 5, 2014 (KR) 10-2014-0026095

(51) Int. Cl. G01R 31/26

(52) U.S. Cl. CPC G01R 31/2607

(57) ABSTRACT

A chip to package interaction (CPI) test vehicle includes a chip including metal patterns contained in first and second sub-regions, respectively, and in which any one of the following comparable properties (a)˜(e) is the same among the first and second sub-regions, and another one of the properties (a)˜(e) is different among the first and second sub-regions: (a) size and shape of the sub-region, (b) metal density of the metal pattern, (c) type of the metal pattern, (d) distance between the sub-region and a center of the chip, (e) structure of the metal pattern.

### PRIORITY STATEMENT

This application claims priority, and all the benefits accruing therefrom under 35 U.S.C. 119, from Korean Patent Application No. 10-2014-0026095 filed on Mar. 5, 2014 in the Korean Intellectual Property Office, the contents of which are hereby incorporated by reference in their entirety.

### BACKGROUND

1. Technical Field

The present inventive concept relates to a chip to package interaction (CPI) test vehicle and to a method for testing chip to package interaction using the same.

2. Description of the Related Art

A manufacturing technology for large scale integrated circuits (LSI) often includes the packaging of a chip comprising the LSI to a substrate having interconnections by which the LSI may be connected to an external device. In this technology, the chip to package interaction (CPI) is critical in realizing a high yield of reliable products. As LSI devices are scaled down, CPI failures, in which the chips do not operate normally, are increasingly occurring. That is, especially when designing LSI devices, CPI margins over which the packaged chips can operate normally under a range of external stresses are decreasing. Many aspects of LSI devices, including the design of the chip and substrate, and the process used to package the chip to the substrate, may account for CPI failures and thus a lowered CPI margin especially as such devices are scaled down under ever decreasing design rules. For example, thermo-mechanical deformations which occur as the chip is bonded to the substrate may affect dielectric layers in the device, particularly those having ultra low dielectric constants (ULK) which are gaining use in today's highly integrated semiconductor devices.

Thus, a CPI test vehicle is created for use in discovering CPI failures in the semiconductor device packages, and especially in LSI semiconductor device products, under design.

### SUMMARY

An aspect of the inventive concept may reside in the provision of a CPI test vehicle capable of establishing a design correlation that maximizes a CPI margin in the development of high-integration and high-performance semiconductor device packages.

Another aspect of the inventive concept may reside in the provision of a method for testing for CPIs in a way that allows for a CPI margin to be maximized in the development of high-integration and high-performance semiconductor device products.

According to one aspect of the inventive concept there is provided a chip to package interaction (CPI) test vehicle including a chip having metal patterns, and in which the chip has first and second sub-regions each containing a respective one of the metal patterns, in which the sub-regions have at least two comparable properties selected from the group including:
(a) size and shape of the sub-region,
(b) density of the metal pattern in the sub-region,
(c) type of the metal pattern,
(d) distance between the sub-region and a center of the chip, and
(e) structure of the metal pattern, and

in which one of the properties (a)-(e) is the same among the first and second sub-regions, and another of the properties of the group differs among the first and second sub-regions.

According to one aspect of the inventive concept there is provided a chip to package interaction (CPI) test vehicle including first and second chips having metal patterns, respectively, and in which the first chip includes first and second sub-regions, in which the second chip includes third and fourth sub-regions, in which the first, second, third and fourth sub-regions have at least two comparable properties selected from the group including:
(a) size and shape of the sub-region,
(b) metal density of the metal pattern,
(c) type of the metal pattern,
(d) distance between the sub-region and a center of the chip,
(e) structure of the metal pattern, and
(f) position of the chip, and

in which one of the properties (a)-(f) is the same among the first, second third and fourth sub-regions, and another of the properties (a)-(f) differs among the first, second, third and fourth sub-regions.

According to one aspect of the inventive concept there is provided a chip to package interaction (CPI) test vehicle including a chip including at least one insulating layer and metal patterns in a plurality of sub-regions spaced from each other across the chip, in which uppermost surfaces of the metal patterns are coplanar and lowermost surfaces of the metal patterns are coplanar such that the sub-regions are all disposed at the same level in the chip, in which the sub-regions have comparable properties selected from the group including:
(a) size and shape of the sub-region,
(b) percentage of the sub-region occupied by the metal pattern as a ratio of the total surface area of the metal pattern to area of the sub-region or total volume of the metal pattern to the volume of the layer of the sub-region containing the metal pattern,
(c) type of pattern constituting the metal pattern in terms of a dimensional characteristic of the metal pattern, and
(d) distance between the sub-region and a center of the chip, and
(e) structure of the metal pattern in terms of the arrangement of features constituting the metal pattern in a case in which the metal pattern has discrete metal features, and

in which one of the properties of the group including properties (a)-(e) is different among respective ones of the sub-regions, and the others of the properties of the group are all the same, respectively, among the sub-regions.

### BRIEF DESCRIPTION OF THE DRAWINGS

The above and other aspects and features of the present inventive concept will become more apparent from the following detailed description of exemplary embodiments thereof made with reference to the attached drawings, in which:

FIG. 1 is a conceptual diagram of a first embodiment of a CPI test vehicle according to the inventive concept;

FIG. 2 is a conceptual diagram of a second embodiment of a CPI test vehicle according to the inventive concept;

FIG. 3 is an enlarged and detailed view of a portion of the CPI test vehicle of FIG. 2;

FIG. 4 is a plan view of a sub-region having a strip type of metal pattern of a CPI test vehicle according to the inventive concept;

FIG. 5 is a plan view of a sub-region having another version of a strip type of metal pattern of a CPI test vehicle according to the inventive concept;

FIG. 6 is a plan view of a sub-region having a stack type of metal pattern of a CPI test vehicle according to the inventive concept;

FIG. 7 is a vertical cross-sectional view taken along line G-G′ of FIG. 6;

FIG. 8 is a vertical cross-sectional view, similar to that of FIG. 6, but showing a stack type of metal pattern in another sub-region of the CPI test vehicle;

FIG. 9 is a plan view of a sub-region having conductive bumps of a CPI test vehicle according to the inventive concept;

FIG. 10 is an enlarged view of a corner of the sub-region shown in FIG. 9;

FIG. 11 is a vertical cross-sectional view taken along line H-H′ of FIG. 10;

FIG. 12 is a plan view of other embodiments of CPI test vehicles according to the inventive concept, and also shows a floorplan by which the embodiments may be generated; and

FIG. 13 is a flowchart of a method for testing CPI according to the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes.

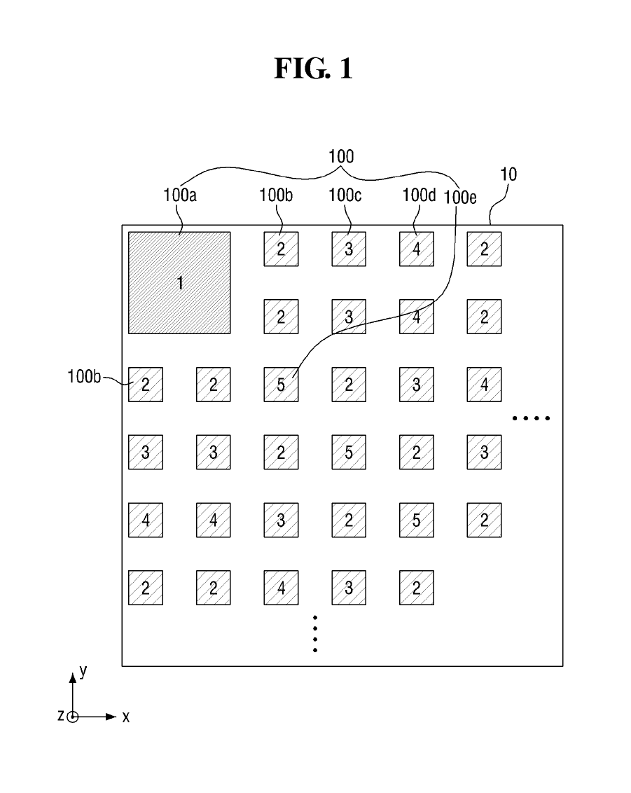

One embodiment of a CPI test vehicle according to the inventive concept will now be described in detail with reference to FIG. 1.

The CPI test vehicle is a chip 10 having a number of sub-regions 100.

The chip 10 may be a semiconductor chip such as a system on chip (SOC) which performs various functions, a logic element, or a semiconductor memory element. The chip 10 has a plurality of sub-regions 100 each including a metal pattern. A sub-region 100 is thus a region of the chip 10 containing a respective metal pattern. In this respect, as the examples that follow will show, lowermost surfaces of the metal patterns are coplanar. In other words, the sub-regions 100 that contain the metal patterns are all disposed at the same level in the chip 10.

The sub-regions 100 may have the same size and shape. However, in the illustrated embodiment, the size of one sub-region 100a (or more than one sub-region 100a) is different from that of the other sub-regions 100b, 100c, 100d and 100e.

In addition, the metal densities of the sub-regions 100 may be different from each other. Metal density refers to the ratio of the area of the metal, constituting the metal pattern within a sub-region 100, to the total area of the sub-region. In the illustrated example of this embodiment, the metal densities of the sub-regions 100 represented by the same number 1 to 5 are the same, but the metal density of each sub-region represented by a particular number 1 to 5 differs from that represented by each of the other numbers 1 to 5.

That is, for example, the sub-regions 100b represented by number 2 have the same metal densities as one another, and the sub-regions 100c represented by number 3 have the same metal densities as one another. However, the metal density of each of the sub-regions 100b represented by number 2 is different from that of each of the sub-regions 100c represented by number 3, each of the sub-regions 100d represented by number 4, and each of the sub-regions 100e represented by number 5.

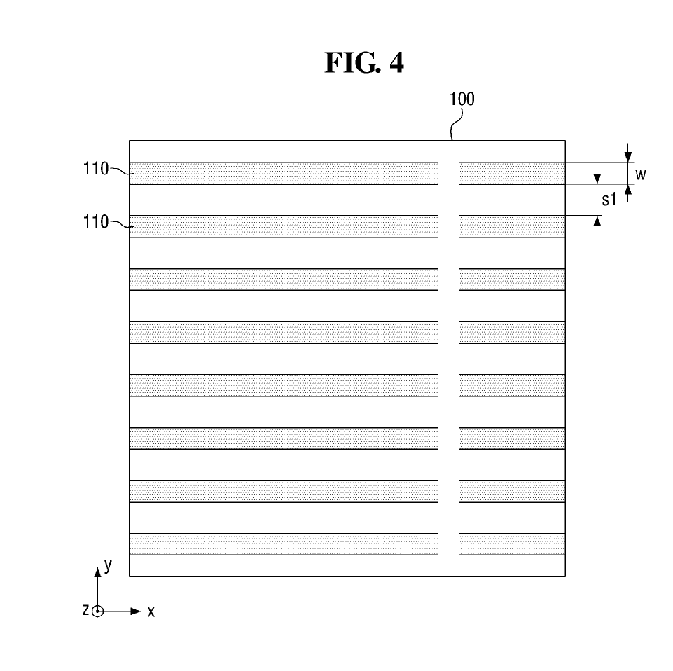

In addition to metal density, the sub-regions 100 may have other comparable properties such as the type of metal pattern therein (an example of which will be described below with reference to FIG. 4), the distance between the sub-region 100 and the center of the chip 10, and a structure of the metal pattern. As described above with respect to the example of the embodiment of FIG. 1, in the case in which the metal densities of respective ones of the sub-regions are different from each other, and the other comparable properties of the sub-regions 100 are same, densities of a metal pattern that give rise to CPI failures can be identified and thus, a CPI margin based on these failures can be determined.

On the other hand, in the case of a conventional CPI test vehicle, a dummy metal pattern is provided at only an edge or corner portion of a chip, and the remaining region of the chip is left empty. In this case, it is only possible to confirm whether a CPI failure occurs and it is impossible to determine the metal densities that will secure the required CPI margin.

In summary, the first embodiment of a CPI test vehicle according to the inventive concept allows for the affect of one property of a device under design on the CPI margin, e.g., the density of a metal pattern constituting the device in this example on the CPI margin, to be determined. This affect can then be relayed into the design of the components of the semiconductor device or the packaging process so as to provide highly reliable devices.

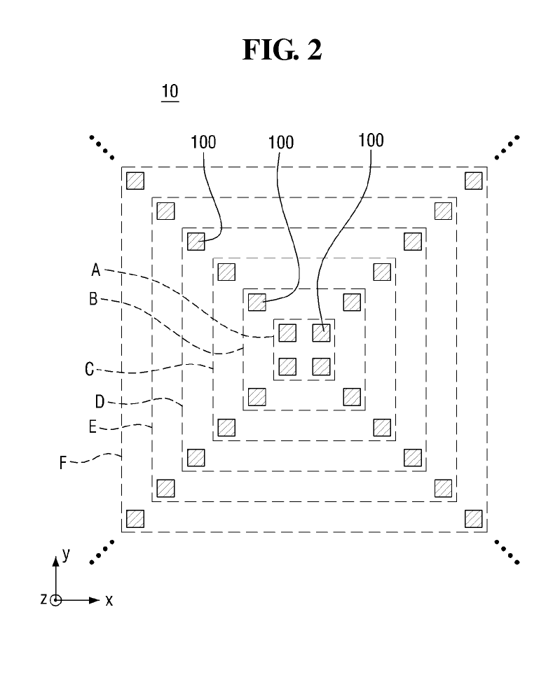

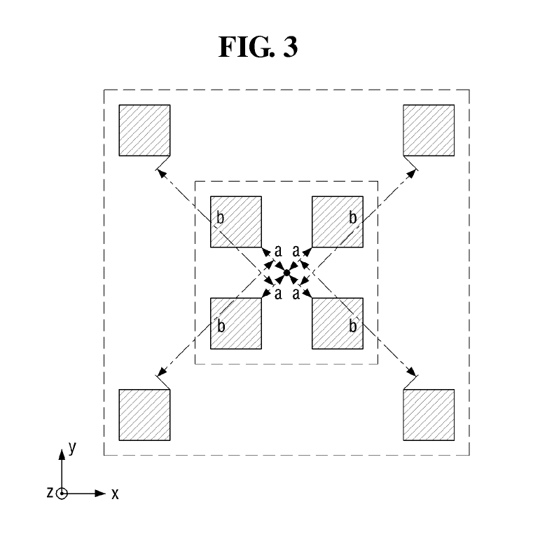

Hereinafter, a second embodiment of a CPI test vehicle according to the inventive concept will be described in detail with reference to FIGS. 2 and 3.

The CPI test vehicle has sections A to F spaced from a neutral point, in this case the geometric center of the chip 10 as viewed in plan; thus, the sections A to F are arrayed along the diagonal from the center of the chip. Each of the sections A to F contains a plurality of sub-regions 100 with the sub-regions 100 in each section A to F disposed the same distance to the neutral point (DNP). In this example, each section A to F is rectangular and contains four sub-regions 100 at the respective corners of the section such that the four sub-regions 100 of each section A to F have the same DNP. That is, each of the sub-regions 100 of section A are spaced the same distance “a” from the center of the chip (FIG. 3), each of the sub-regions 100 of section B of the chip are spaced the same distance “b” from the center of the chip, etc., and the distances “a”, “b” differ from each other.

However, the direction in the chip along which the DNP is taken is not limited to the diagonal. That is, the direction in the chip along which the DNP varies may be a direction other than the diagonal of the chip.

Also, in this embodiment of a CPI test vehicle according to the inventive concept, the so-called comparable properties of the sub-regions 100, other than the DNP, are all the same among the sub-regions 100. For example, amongst the sub-regions 100, the size of each sub-region 100, the density of the metal pattern of each sub-region 100, the type of metal pattern of each sub-region 100, and the structure of the metal pattern of each sub-region 100 may all be the same. In other embodiments, however, in addition to the DNP at least one of the other comparable properties differs among the sub-regions 100.

An example of a two-dimensional type of metal pattern contained in sub-regions 100 of a CPI test vehicle, according to the inventive concept will be described with reference to FIG. 4.

One embodiment of a CPI test vehicle employing this type of metal pattern according to the inventive concept has the form shown in FIG. 1 in which the sub-regions 100 have the same shape and at least one of the sub-regions 100a has a different size than the other sub-regions 100b, 100c . . . 100e. In another embodiment, all of the sub-regions 100 have the same size and shape.

Referring to FIG. 4, in either of these embodiments, the respective metal patterns of the sub-regions 100 are all of the same type, e.g., a strip type consisting of parallel metal lines 110. However, the width w and spacing s1 of the metal lines 110 differ among the respective metal patterns of the sub-regions 100.

Accordingly, the metal densities of the sub-regions 100 differ from each other.

Thus, as described above, in the case in which the metal densities of the sub-regions are different from each other across the CPI test vehicle, and the other comparable properties of the sub-regions are the same, it is possible to develop a correlation between CPI margin and the density of a metal pattern constituting a semiconductor device package under design.

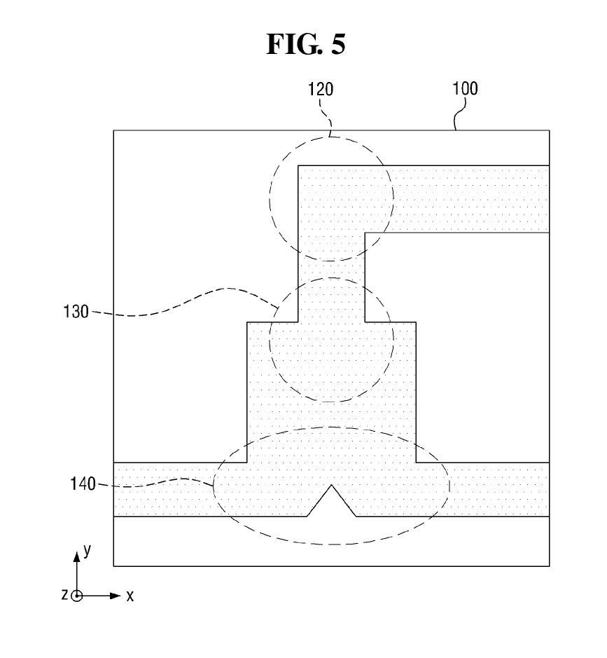

Another example of a two-dimensional type of metal pattern contained in sub-regions 100 of a CPI test vehicle, according the inventive concept, will now be described in detail with reference to FIG. 5.

One embodiment of a CPI test vehicle employing this type of metal pattern according to the inventive concept has the form shown in FIG. 1 in which the sub-regions 100 have the same shape and at least one of the sub-regions 100a has a different size than the other sub-regions 100b, 100c . . . 100e. In another embodiment, all of the sub-regions 100 have the same size and shape.

All the sub-regions 100 of the present embodiment may include metal patterns of the same type, i.e., a strip type. However, the strip type metal patterns may include patterns having various shapes as well as the metal lines 110.

As illustrated, the metal pattern may include a section 120 of wiring at which two metal lines intersect at an angle, e.g. at a right angle, a section 130 of straight wiring along which the width varies, and a section 140 of wiring where a split occurs.

The shape of the metal pattern shown in FIG. 5 is altered among the various sub-regions 100 across the CPI test vehicle. However, the metal patterns are designed so that the sub-regions 100 have the same metal densities despite the different shapes of the respective metal patterns. For example, the change in width at section 130 of the metal pattern may vary from sub-region to sub-region, while the widths of other sections of the wiring are also varied so that despite the different planar shapes of the metal patterns the densities of the metal patterns are the same amongst the sub-regions.

As described above, in the case where the planar shapes of the metal patterns are different from each other, the other comparable properties are to be the same. That is, since only the planar shapes of the metal patterns of the sub-regions 100 are different and the other comparable properties are the same, it is possible to identify significant differences in CPI margins attributable to the particular planar shape of the metal pattern of the semiconductor device package under design.

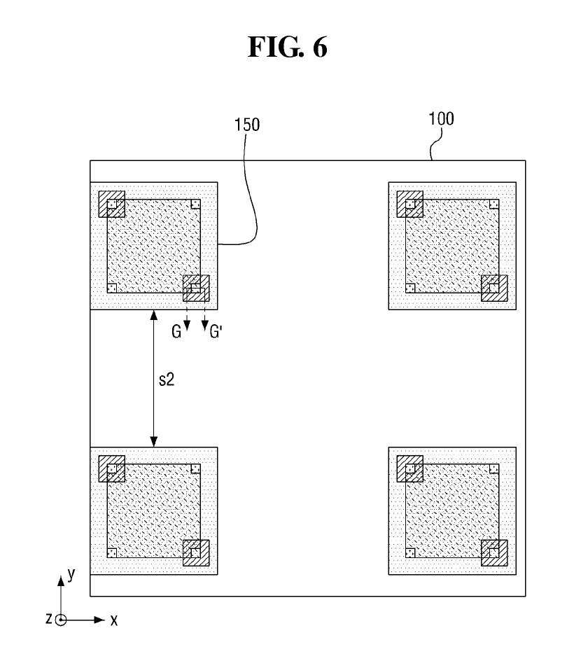

Hereinafter, an example of a three-dimensional type of metal pattern contained in sub-regions 100 of a CPI test vehicle, according to the inventive concept, will be described with reference to FIGS. 6 to 8. That is, FIGS. 6-8 illustrate a stack type of metal pattern of embodiments of a CPI test vehicle according to the inventive concept.

One embodiment of a CPI test vehicle employing this stack type of metal pattern according to the inventive concept has the form shown in FIG. 1 in which the sub-regions 100 have the same shape and at least one of the sub-regions 100a has a different size than the other sub-regions 100b, 100c . . . 100e. In another embodiment, all of the sub-regions 100 have the same size and shape.

In either of these embodiments, though, all of the sub-regions 100 include a metal pattern of the same three-dimensional type, i.e., a stack type. For example, each of the sub-regions 100 includes metal layers 152, interlayer dielectric (ILD) layers 154 and vias 156a or 156b.

The metal layers 152 and the ILD layers 154 have the form of any of various structures in a semiconductor device, such as those of elements constituting transistors or the like. The vias 156a and/or 156b pass through the ILD layers 154 and contact the metal layers 152.

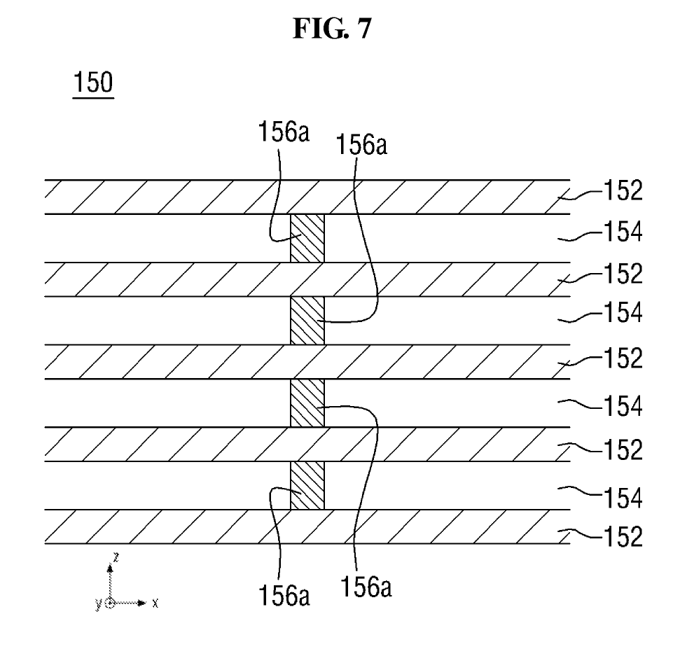

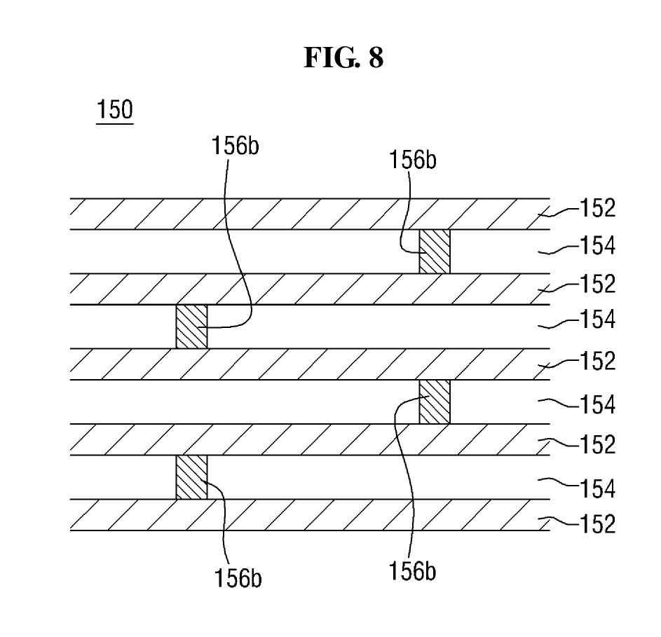

The stack type metal patterns vary among the sub-regions 100 so as to have different structures. A characteristic of the pattern which may differentiate the structures may be the number of the metal layers 152, the number of the ILD layers 154, the number of the vias, the density of the vias in the sub-region (in this case, the metal density of a sub-region may refer to the total volume of the metal vias to the total volume of the sub-region containing the vias), or the arrangement of the vias (described in more detail below with reference to FIGS. 7 and 8).

Therefore, the above-listed characteristics can be regarded as the comparable properties of the sub-regions 100. Thus, any one of these characteristics of the metal patterns may vary among the sub-regions 100 while all of the other characteristics of the metal patterns of the respective sub-regions may be the same. That is, for example, the arrangement of the vias constituting the metal patterns may be different among the sub-regions 100 and the other characteristics of the same metal patterns, i.e., the number of the metal layers 152, the number of the ILD layers 154, the number of the vias, and the metal density associated with the vias may be the same among the sub-regions 100. This will now be described in more detail with reference to FIGS. 7 and 8.

Referring to FIG. 7, in one of the sub-regions 100, vias 156a pass through all of the ILD layers 154, respectively, between the metal layers 152, and each via 156a that passes through one of the ILD layers 154 is vertically aligned with the vias 156a that pass through the other ILD layers 154. Also, as is clear from FIG. 6, several sets of such vertically aligned vias 156a are provided in the sub-region. Accordingly, several vertical conductive paths extend from the uppermost metal layer 152 to the lowermost metal layer 152 in the sub-region.

On the other hand, referring to FIG. 8, in another of the sub-regions 100, vias 156b pass through all of the ILD layers 154, respectively, between the metal layers 152, but vertically adjacent ones of the vias 156b are arranged as horizontally offset from one another so that the vias 156b are not vertically aligned. Thus, the vias 156b provide a zigzagging conductive path from the uppermost metal layer 152 to the lowermost metal layer 152 in the sub-region.

In a CPI test vehicle having respective sub-regions 100 as shown in FIGS. 7 and 8, the “structure” of the metal pattern differs among respective ones of the sub-regions, whereas another comparable property (properties) of the sub-regions is (are) the same. That is, one of the sub-regions 100 has the vias 156a (vertically aligned arrangement of vias) and another of the sub-regions 100 has the vias 156b (offset arrangement of vias) and yet the sub-regions have the same metal densities. Because only the arrangement of the vias of the metal patterns of the sub-regions 100 is different and the other comparable properties are the same, it is possible to identify a significant difference of the CPI margin according to the arrangement of the vias (structure of the metal pattern).

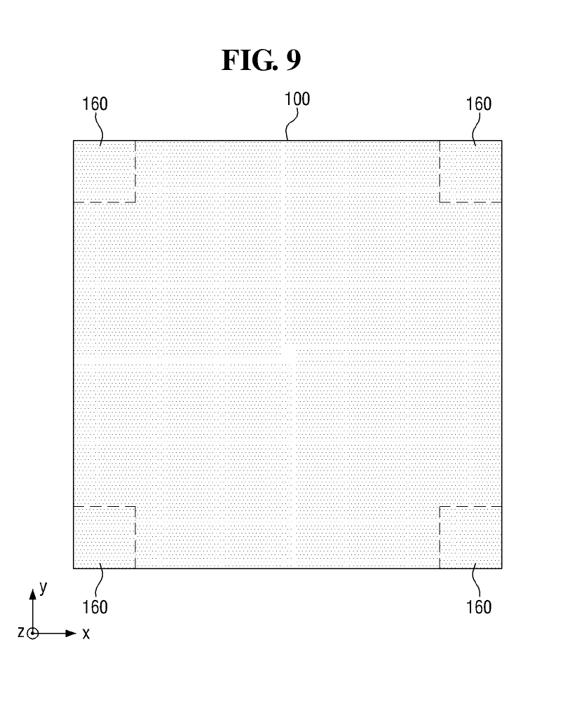

Hereinafter, another embodiment of a CPI test vehicle according to the inventive concept will be described with reference to FIGS. 9 to 11. In this embodiment, metal bumps 200 are provided in each of the sub-regions 100. The bumps 200 may be formed of copper. Furthermore, the bumps 200 may be provided on a metal pattern such as that shown in and described with reference to FIG. 4. Thus, in this case, the upper portion of each sub-region 100 contains the bumps 200 and the lower portion of each sub-region contains a metal pattern on which the bumps 200 are formed.

Referring to FIG. 9, in principle, the bumps 200 contained in each sub-region 100 may be disposed uniformly across the sub-region 100. However, corner portions 160 of the sub-regions are more likely to be damaged. Thus, the arrangement of the bumps 200 may be varied at only the corner portions 160 among the sub-regions 100, as will be described in more detail below.

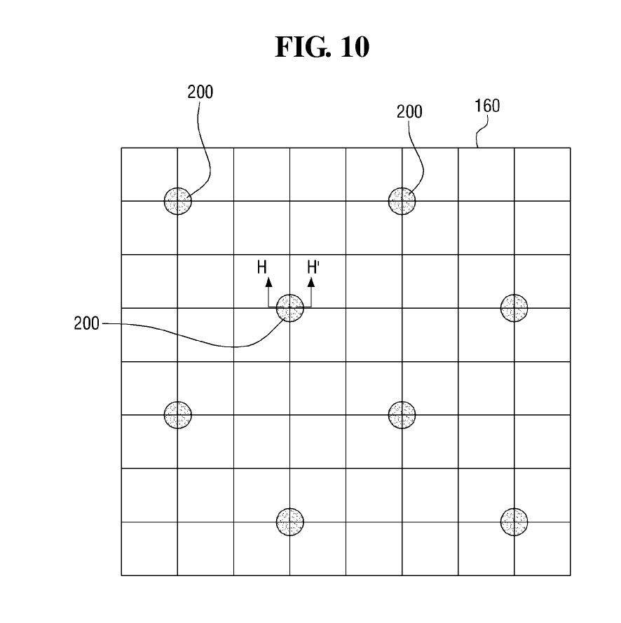

Referring to FIG. 10, in each sub-region, though, the bumps 200 may be arranged (in the corner 160) at regular pitches in the horizontal plane.

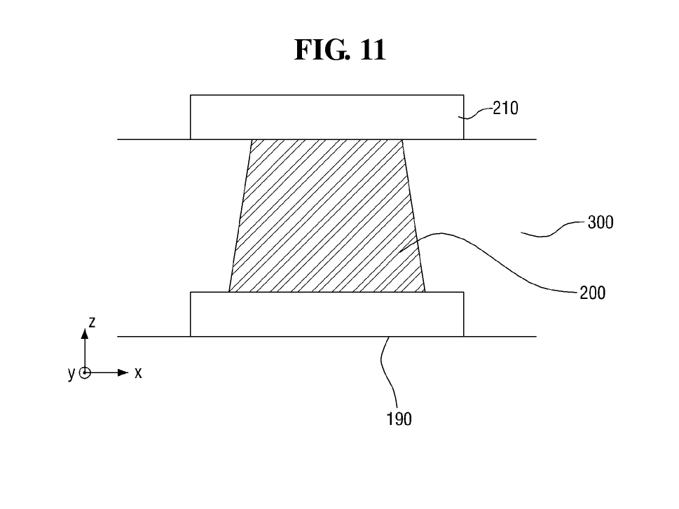

Referring to FIG. 11, the bottom of each bump 200 may contact a first metal wiring 190. The bump 200 may pass through an insulating layer 300. The bump 200 may be electrically connected to an external wiring 210. A width of the lower portion of the bump 200 may be greater than a width of the upper portion.

In a conventional CPI test vehicle, only the pitch of the bumps is considered.

On the other hand, in one example of this embodiment of a CPI test vehicle according to the inventive concept, it is possible to identify the affect of a comparable property, other than one associated with the bumps 200, on CPI failure by arranging the bumps 200 uniformly in all the sub-regions 100. For example, the bumps 200 in the upper portions of the sub-regions may be uniform among the sub-regions 100, and the metal density or the type of metal pattern in the lower portions of the sub-regions 100 may be different among the sub-regions 100.

In another example, all of the comparable properties of the lower portions of the sub-regions 100, such as the density of the metal pattern, etc., may be the same among the sub-regions 100, and a comparable property of the upper portions of the sub-regions 100, i.e., a characteristic of the bumps 200, may be different among the sub-regions 100.

More specifically, in an example of this embodiment of a CPI test vehicle according to the inventive concept, the arrangement density of the bumps 200 is different among the sub-regions 100, while all of the other comparable properties of the sub-regions (including those of the lower portions of the sub-regions 100 containing the metal patterns) are the same among the sub-regions 100. In this respect, arrangement density refers to the pitch of the bumps 200 and thus, may correspond to the number of bumps per unit area (in the corner 160) of the sub-region 100. Also, recall that the comparable properties of the sub-regions may include the size and shape of each of the sub-regions 100, the metal density of the metal pattern, the type of metal pattern, the DNP of the sub-regions 100, the structure of the metal pattern.

Thus, for example, the affect of the arrangement density of the bumps 200 on the CPI margin may be determined.

In another example of this embodiment, the metal density of the bumps 200 is different among the sub-regions 100 while all of the other comparable properties of the sub-regions are the same among the sub-regions 100. Metal density of the bumps refers to the ratio of total volume of the bumps (in the corner 160) of the sub-region 100 to the total volume of a layer (of the corner 160) of the sub-region 100 containing the bumps.

Thus, for example, the affect of the metal density of the bumps 200 on the CPI margin may be determined.

Accordingly, this embodiment of a CPI test vehicle according to the inventive concept can be used to ensure a sufficient CPI margin in a semiconductor device package having conductive bumps similar to the bumps 200.

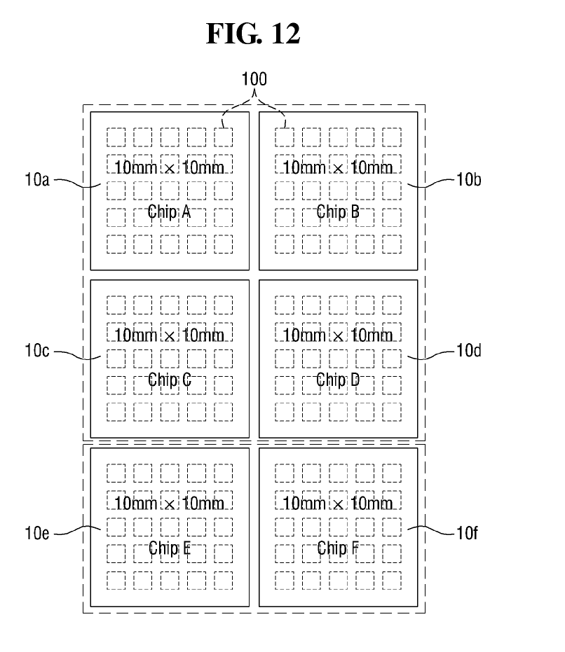

Hereinafter, a CPI test vehicle according to a seventh embodiment of the inventive concept will be described with reference to FIG. 12.

FIG. 12 is a floor plan of chips for explaining the CPI test vehicle according to the seventh embodiment of the inventive concept.

Referring to FIG. 12, the CPI test vehicle according to the seventh embodiment of the inventive concept includes a plurality of chips 10a, 10b, 10c, 10d, 10e and 10f. A conventional floorplan has chips of different sizes by which a package is freely formed.

On the other hand, in the CPI test vehicle of the present embodiment, the chips 10a, 10b, 10c, 10d, 10e and 10f have the same shape and size. Further, in the CPI test vehicle of the present embodiment, each of the chips 10a, 10b, 10c, 10d, 10e and 10f may have a rectangular shape. Thus, adjacent ones of the chips 10a, 10b, 10c, 10d, 10e and 10f may be circumscribed within any of several different rectangles (two of which are shown in the example of FIG. 12 within the dashed lines). Accordingly, it is possible to form a CPI test vehicle including an even number (two or four, etc.) of chips 10a, 10b, 10c, 10d, 10e and 10f, instead of simply one chip 10a, by slicing the floorplan along one line. In this manner, it is possible to determine an affect of the position of any chip 10a, 10b, 10c, 10d, 10e and 10f relative to one or more other chips on CPI failures.

Also, in this embodiment of the CPI test vehicle, each of the chips 10a, 10b, 10c, 10d, 10e and 10f may have a plurality of sub-regions 100 of any type described above containing a metal pattern. The comparable properties of the sub-regions 100, i.e., the size and shape of the sub-region, the metal density of the metal pattern contained in the sub-region, the type of the metal pattern, and the structure of the metal pattern, may be the same among the sub-regions.

The sub-regions 100 may be provided in the corners of the chips. Generally, an outer peripheral straight edge portion of the chip will be weaker, i.e., less durable, than a central portion of the chip, and a corner portion of the chip will be weaker than the outer peripheral straight edge portion of the chip. Accordingly, it is necessary to intensively check CPI failures at the corner portion.

Thus, the sub-regions 100 of the chips 10a, 10b, 10c, 10d, 10e and 10f at the corners of the chips can be used to indentify the positioning of a chip relative to another or other chips on CPI failure.

For example, in the case of sawing four chips A, B, C and D as one piece and packaging the four chips as joined together on a substrate, a right bottom corner of chip A (10a) and a left bottom corner of chip B (10b) are adjacent to the other chips (chips B, C, D in the case of chip A and chips A, C, D in the case of chip B). Therefore, by comparing results of a test on the sub-regions 100 at a left bottom corner and a right bottom corner of chip A (10a), for example, it is possible to determine the affect of the separation and arrangement of the chips, i.e., the affect of the slice selected, on CPI margin. (Note, in this example the spatial terms relate to the drawing of FIG. 12 and not actual use).

Hereinafter, an embodiment of a method for testing CPI according to the inventive concept will be described with reference to FIGS. 1 to 13. Detailed descriptions of the CPI test vehicle according the inventive concept will be simplified or omitted.

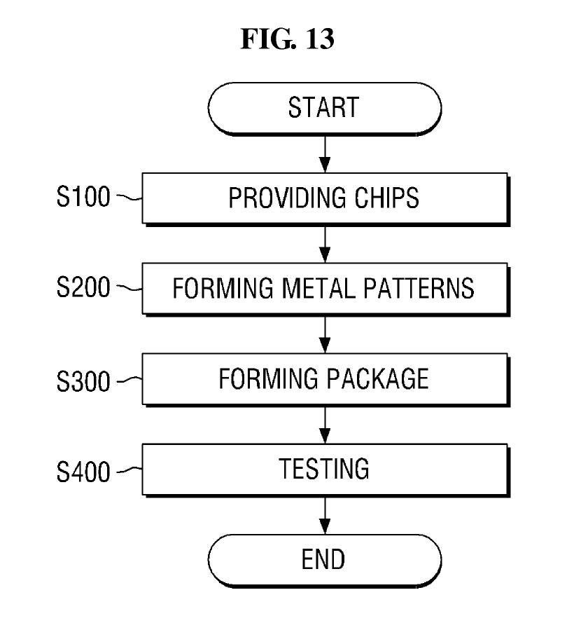

Referring to FIG. 13, chips, each of which is divided into sub-regions 100, are provided (step S100).

Referring to FIGS. 1 and 12, each of the chips 10a, 10b, 10c, 10d, 10e and 10f may be a semiconductor chip such as a system on chip (SOC) which performs various functions, a logic element, or a semiconductor memory element. The chips 10a, 10b, 10c, 10d, 10e and 10f may include metal patterns. The chips 10a, 10b, 10c, 10d, 10e and 10f may have the same size and shape according to a predetermined standard, but are not limited to being of the same size and shape. All of the sub-regions 100 may have the same size and shape but, as described above with reference to FIG. 1, the size or shape of the sub-regions 100 may vary among the sub-regions 100.

Referring again to FIG. 13, metal patterns are formed on the chips within the sub-regions 100 (step S200).

Referring to FIGS. 1 to 8, any one of the metal density of the metal patterns, the type of metal patterns, the structure of the metal patterns, the size and shape of the sub-regions 100, may be different among the sub-regions 100. In the case in which the sub-regions 100 are formed to have different metal densities, the metal densities may differ from each other in a range of 1% to 80%.

Furthermore, each of the chips 10a, 10b, 10c, 10d, 10e and 10f may have sub-regions 100 as shown in FIG. 2, in which the DNP varies among the sub-regions 100 in each chip.

The type of the metal pattern formed in the sub-regions 100 may be a stack type (3-dimensional as shown in and described with reference to FIGS. 6-8) or strip type (planar as shown in and described with reference to FIG. 4 or FIG. 5). However, stack type of metal patterns may be formed in some of the sub-regions 100 while strip type of metal patterns may be formed in the remaining sub-regions 100. In this case, the other comparable properties of the sub-regions 100, such as the metal density of the metal patterns and the size and shape of the sub-regions 100, are designed to be the same. Accordingly, the type of metal pattern that can ensure a larger CPI margin can be determined.

In another example of this method, the metal patterns have the same structure among the sub-regions 100. For example, the metal patterns may all be of a strip type, and the width w and spacing s1 of the metal lines varies among the metal patterns contained in the sub-regions, or the planar shape varies among the metal patterns contained in the sub-regions. In still another example, the metal patterns are all of a stack type (FIGS. 6-8), but the number of the metal layers 152, the number of the ILD layers 154, the number of the vias 156a and 156b, the metal density of the vias 156a and 156b, or the arrangement of the vias 156a and 156b varies among the metal patterns in the sub-regions.

Referring again to FIG. 13, a package including chips is formed (step S300) thereby completing the formation of a CPI test vehicle.

Moreover, this step (S300) may include a process of forming bumps on the metal patterns as shown in and described with reference to FIGS. 9 to 12. The bumps 200 may be formed at the same density among all the sub-regions 100. In this case, it is possible to exclude the influence of the bumps 200, and determine a CPI margin base on the metal patterns in the lower portions of the sub-regions.

Alternatively, all of the comparable properties of the metal patterns constituting the lower portions of the sub-regions 100 are the same, and the bumps 200 may be formed such that their density (volume of bumps to total volume of the layer of the sub-region containing the bumps) or pitch (number per unit area of the sub-region) differ among the sub-regions so that a CPI margin based on the design of the bumps 200 can be determined.

Referring again to FIG. 13, the CPI of the package is tested (step S400).

The CPI test is performed on each of the sub-regions 100. The CPI test may be a test for determining whether an electrical connection is satisfactorily provided in the package through the sub-regions. Alternatively, the CPI test may comprise mechanically testing the sub-regions, i.e., a mechanical stress test.

In the method for testing for CPI failures according to the inventive concept, it is possible to identify exactly how a particular characteristic or property of the package affects the CPI margin. In particular, it is possible to not only identify any cause of CPI failure in the entire process of designing a chip or chips of a semiconductor device package, but also to identify a cause of CPI associated with a particular process of manufacturing he chips or packaging the chips.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A chip to package interaction (CPI) test vehicle, comprising:
a chip including metal patterns,
wherein the chip has first and second sub-regions each containing a respective one of the metal patterns, and
wherein the sub-regions have at least two comparable properties selected from the group including:
(a) size and shape of the sub-region,
(b) density of the metal pattern in the sub-region,
(c) type of the metal pattern,
(d) distance between the sub-region and a center of the chip, and
(e) structure of the metal pattern, and
wherein one of the properties (a)-(e) is the same among the first and second sub-regions, and another of the properties of the group differs among the first and second sub-regions.

2. The CPI test vehicle of claim 1, wherein the first sub-region and the second sub-region have the same size and shape.

3. The CPI test vehicle of claim 1, wherein the chip further includes bumps disposed on the metal patterns, and
wherein the group of comparable properties further includes:
(f) density of the bumps on the sub-region, and
(g) metal density of the bumps, and
wherein one of the properties (a)-(g) is the same among the first and second sub-regions, and another of the properties (a)-(g) differs among the first and second sub-regions.

4. The CPI test vehicle of claim 3, wherein the density of the metal pattern contained in the first sub-region is different among the first and second sub-regions, and
wherein the presence/absence of the bumps and the metal density of the bumps are the same among the first and second sub-regions.

5. The CPI test vehicle of claim 1, wherein the metal pattern includes at least one strip of metal, and
wherein the metal density of the metal pattern is different among the first and second sub-regions.

6. The CPI test vehicle of claim 5, wherein the metal pattern is a pattern of spaced apart metal lines, and
wherein the width and spacing of the metal lines of the metal pattern is different among the first and second sub-regions.

7. The CPI test vehicle of claim 1, wherein the metal pattern includes a strip of metal having a planar shape, and
wherein the planar shapes of the metal patterns are different among the first sub-region and the second sub-region.

8. The CPI test vehicle of claim 1, wherein the metal pattern is of a stack type in which metal and interlayer dielectric (ILD) layers are alternately stacked one on the other, and includes vias passing through the ILD layers and electrically connecting the metal layers with each other, and
wherein the structure of the metal pattern includes the properties of:
number of the stacked metal layers or vias,
metal density of the vias, and
arrangement of the vias.

9. The CPI test vehicle of claim 8, wherein the arrangement of the vias is different among the first and second sub-regions, and
the number of the stacked metal layers or vias is the same among the first and second sub-regions.

10. The CPI test vehicle of claim 1, wherein the chip is rectangular, and a distance to neutral point (DNP), which is a distance from a center of the chip along the diagonal of the chip to a sub-region, is different between the first and second sub-regions.

11. A chip to package interaction (CPI) test vehicle, comprising:
first and second chips including metal patterns, respectively,
wherein the first chip includes first and second sub-regions,
wherein the second chip includes third and fourth sub-regions,
wherein the first, second, third and fourth sub-regions have at least two comparable properties selected from the group including:
(a) size and shape of the sub-region,
(b) metal density of the metal pattern,
(c) type of the metal pattern,
(d) distance between the sub-region and a center of the chip,
(e) structure of the metal pattern, and
(f) position of the chip, and
wherein one of the properties (a)-(f) is the same among the first, second third and fourth sub-regions, and another of the properties (a)-(f) differs among the first, second, third and fourth sub-regions.

12. The CPI test vehicle of claim 11, wherein the position of the chip of the first and second sub-regions is different from the position of the chip of the third and fourth sub-regions, and all of the properties (a)-(e) are the same among the sub-regions.

13. The CPI test vehicle of claim 11, wherein the first sub-region is located at a corner of the first chip,
wherein the third sub-region is located at a corner of the third chip, and
wherein all of the properties (a)-(e) are the same among the first and third sub-regions.

14. The CPI test vehicle of claim 11, wherein each of the first and second chips further includes bumps disposed on the metal patterns, and
wherein the group of comparable properties further includes:
(g) arrangement density of the bumps on the sub-region
(h) metal density of the bumps,
such that one of the properties (a)-(h) is the same among the first, second third and fourth sub-regions, and another of the properties (a)-(h) differs among the first, second, third and fourth sub-regions.

15. The CPI test vehicle of claim 14, wherein the first sub-region is located at a corner of the first chip,
wherein the third sub-region is located at a corner of the third chip, and
wherein all of the properties (a)-(g) are the same among the first and third sub-regions.

16. A chip to package interaction (CPI) test vehicle, comprising:
a chip including at least one insulating layer and metal patterns in a plurality of sub-regions spaced from each other across the chip,
wherein lowermost surfaces of the metal patterns are coplanar such that the sub-regions are all disposed at the same level in the chip,
wherein the sub-regions have comparable properties selected from the group including:
(a) size and shape of the sub-region,
(b) percentage of the sub-region occupied by the metal pattern as a ratio of the total surface area of the metal pattern to area of the sub-region or total volume of the metal pattern to the volume of the layer of the sub-region containing the metal pattern,
(c) type of pattern constituting the metal pattern in terms of a dimensional characteristic of the metal pattern, and
(d) distance between the sub-region and a center of the chip, and
(e) structure of the metal pattern in terms of the number or arrangement of metal features constituting the metal pattern in a case in which the metal pattern has discrete metal features, and
wherein one of the properties of the group including properties (a)-(e) is different among respective ones of the sub-regions, and the others of the properties of the group are all the same, respectively, among the sub-regions.

17. The CPI test vehicle of claim 16, wherein each of the metal patterns is a pattern of spaced apart metal lines on the insulating layer, and said one of the properties is property (c) with the widths and/or the spacing of the metal lines of the metal patterns differing among the metal patterns contained in said respective ones of the sub-regions.

18. The CPI test vehicle of claim 16, wherein each of the metal patterns is a section of metal wiring extending along the insulating layer, and said one of the properties is property (c) with widths of the sections of the metal wiring of the metal patterns differing among the metal patterns contained in said respective ones of the sub-regions.

19. The CPI test vehicle of claim 16, wherein the chip includes, in each of the sub-regions, a plurality of interlayer dielectric (ILD) and metal layers alternately stacked one on the other, and a set of vias extending through the ILD layers, the set of vias constituting the metal pattern of the sub-region,
wherein the structure of the metal pattern includes the properties of:
number of the stacked metal layers or vias,
total volume of the vias in said set to the volume of the sub-region containing the set of vias, and
arrangement of the vias, and
wherein said one of the properties is property (e).

20. The CPI test vehicle of claim 16, wherein the chip further includes sets of bumps disposed on the metal patterns, respectively, and
wherein the group of comparable properties further includes:
(f) the number of bumps in each set thereof, and
(g) a pitch of the bumps, and
wherein said one of the properties is property (f) or (g).
